(19) United States
(12) Patent Application Publication
(10) Pub. No.: US 2026/0271704 A1
(43) Pub. Date: Sep. 10, 2026

(54) INTERCONNECT STRUCTURE INCLUDING MULTILAYERED DIELECTRIC FILM SCHEME AND METHOD FOR MANUFACTURING THE SAME

(71) Applicant: TAIWAN SEMICONDUCTOR MANUFACTURING COMPANY, LTD., Hsinchu (TW)

(72) Inventor: Kai-Fang Cheng, Hsinchu (TW)

(73) Assignee: TAIWAN SEMICONDUCTOR MANUFACTURING COMPANY, LTD., Hsinchu (TW)

(21) Appl. No.: 19/072,401

(22) Filed: Mar. 6, 2025

(51) Int. Cl. H01L 23/532; H01L 21/31; H01L 21/768; H01L 23/522

(52) U.S. Cl. CPC H10W 20/47; H10P 14/60; H10W 20/081; H10W 20/42

(57) ABSTRACT

A method for manufacturing an interconnect structure includes: forming a first interconnect layer on a substrate, the first interconnect layer being formed with a first conductive feature; forming a first metal-based dielectric layer on the first interconnect layer, the first metal-based dielectric layer including a first metal-based dielectric material; forming a second metal-based dielectric layer on the first metal-based dielectric layer, the second metal-based dielectric layer including a second metal-based dielectric material which is different from the first metal-based dielectric material; and forming a second interconnect layer on the second metal-based dielectric layer, the second interconnect layer being formed with a second conductive feature that penetrates each of the second metal-based dielectric layer and the first metal-based dielectric layer, so that the second conductive feature is connected to the first conductive feature.

### BACKGROUND

Scaling down of devices continues to drive advancements in semiconductor technology, with nodes reaching sub-5 nm processes. This trend focuses on improving transistor performance, reducing power consumption, and enhancing chip density. The back end of line (BEOL) is progressing to address increased complexity, and incorporates advanced materials and interconnects to maintain device performance at smaller scales. Device reliability remains a key research area, with a focus on addressing issues such as electromigration, stress-induced voiding, and the effects of advanced packaging. Ongoing research also explores AI-driven design and manufacturing techniques to optimize these processes and ensure long-term chip reliability in increasingly demanding applications.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing an interconnect structure in accordance with some embodiments.

FIGS. 2 to 12 are schematic views illustrating intermediate stages of the method depicted in FIG. 1 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±20%, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions and could be understood by those skilled in the art after reviewing the present disclosure.

The term “source/drain portion(s)” may refer to a source or a drain, individually or collectively dependent upon the context.

Thermal torture test is a reliability test to determine the stability of equipment or materials by exposing the equipment or materials to extreme high temperature and high pressure environments so as to verify their performance under extreme conditions. The present disclosure is directed to an interconnect structure capable of passing the reliability test (e.g., the thermal torture test) and a method for manufacturing the same.

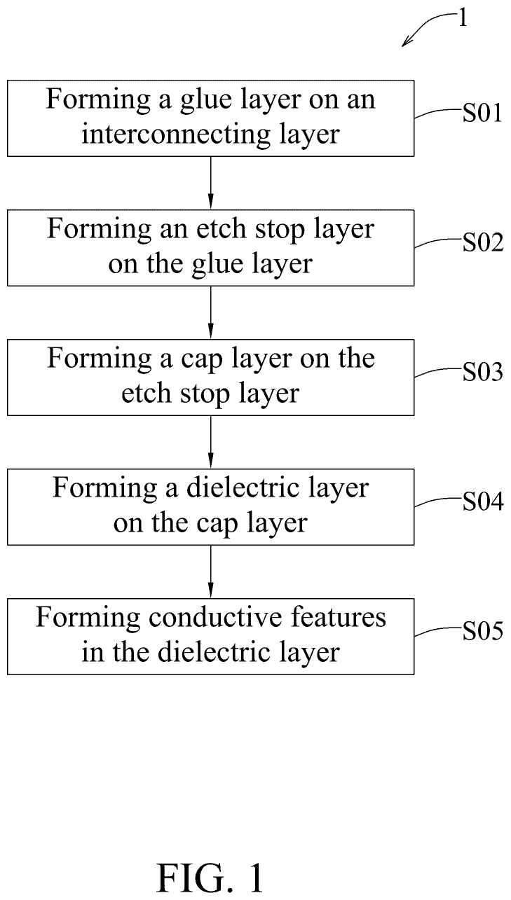

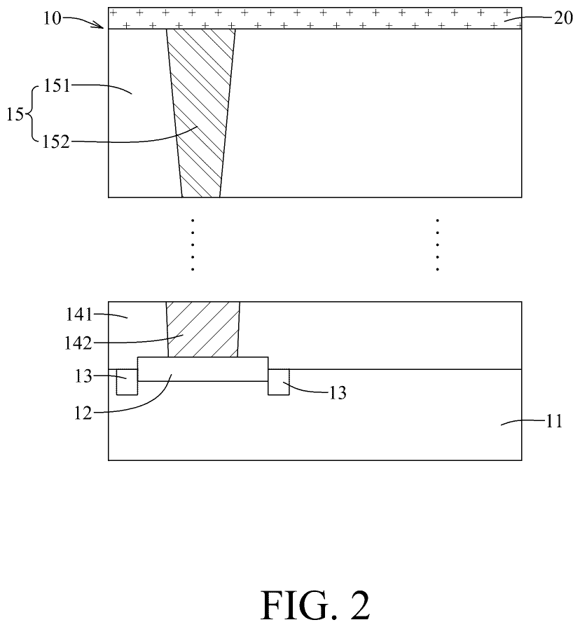

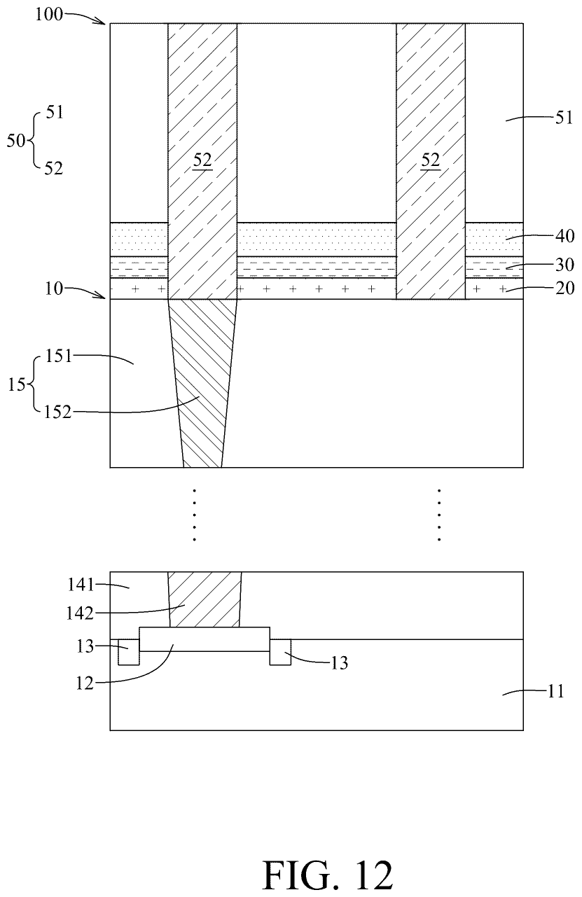

FIG. 1 is a flow diagram illustrating a method 1 for manufacturing an interconnect structure (e.g., an interconnect structure 100 shown in FIG. 12) in accordance with some embodiments. The method 1 may include steps S01 to S05. FIGS. 2 to 12 are schematic views illustrating intermediate stages of the method 1 in accordance with some embodiments. Some repeating structures are omitted in FIGS. 2 to 12 for the sake of brevity.

In some embodiments, the interconnect structure is formed on a front side of a base structure 10 (see, for example, FIG. 12). In some embodiments not shown herein, the interconnect structure may be formed on a back side of the base structure 10 opposite to the front side.

In some embodiments, the base structure 10 is a device wafer including active devices (for example, transistors, diodes, or the like), passive devices (for example, capacitors, inductors, resistors, or the like), memory devices, decoders, amplifiers, or combinations thereof. In some embodiments, as shown in FIG. 12, the base structure 10 includes a substrate 11, a plurality of semiconductor devices 12 (one of which is exemplarily shown in, for example, FIG. 12) formed on or in the substrate 11, an inter-layer dielectric (ILD) layer 141 on the substrate 11 to cover the semiconductor devices 12, and metal contacts 142 (one of which is exemplarily shown in, for example, FIG. 12) formed in the ILD layer 141 and connected to the semiconductor devices 12.

In some embodiments, the substrate 11 may include elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In some embodiments, the substrate 11 may be a bulk semiconductor substrate, for example, but not limited to, a bulk substrate of silicon, germanium, silicon germanium, or other suitable semiconductor materials (such as the examples described earlier in the same paragraph). In some other embodiments not shown herein, the substrate 11 may be configured as a semiconductor-on-insulator substrate. Other suitable materials and configurations for the substrate 11 are within the contemplated scope of the present disclosure. In some embodiments, the substrate 11 may be formed with trench isolations 13 to separate two adjacent ones of the semiconductor devices 12 from each other. In some embodiments, the trench isolations 13 may each be a shallow trench isolation (STI), a deep trench isolation (DTI), or other suitable structures. In some embodiments, the trench isolations 13 may include silicon oxide, silicon nitride, silicon oxynitride, other low-k (low-dielectric constant) dielectric materials, or combinations thereof.

In some embodiments, each of the semiconductor devices 12 may include a transistor, but is not limited thereto. The transistor may be configured as a planar transistor, a fin-type field-effect transistor (FinFET), a gate-all-around field-effect transistor (GAAFET), a forksheet field-effect transistor, a complementary field-effect transistor (CFET), or other transistors with suitable configuration.

In some embodiments, the ILD layer 141 includes or is made of a low-k dielectric material such as silicon oxide, silicon oxycarbide, silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOC), spin-on-glass (SOG), fluorine-doped silicon oxide, carbon-doped silicon oxide, porous silicon oxide, porous carbon-doped silicon oxide, other suitable low-k dielectric materials, or combinations thereof. In some embodiments, each of the metal contacts 142 is connected to a gate electrode or a source/drain portion of a corresponding one of the semiconductor devices 12. In some embodiments, each of the metal contacts 142 includes or is made of Co, Cu, Ni, Ru, W, Mo, Ti, Al, Ir, Rh, Zr, Ta, Zn, alloys thereof, graphene, other suitable conductive materials, or combinations thereof.

In some embodiments, the base structure 10 further includes an interconnect layer 15 formed on the ILD layer 141. In some embodiments, the interconnect layer 15 includes a dielectric layer 151 and conductive features 152 (one of which is exemplarily shown in, for example, FIG. 12) formed in the dielectric layer 151. In some embodiments, each of the conductive features 152 may be configured as a conductive via or a conductive line which is connected to a conductive feature (not shown) that is located therebeneath, such that each of the semiconductor devices 12 may be electrically connected to an external circuit through corresponding ones of the metal contacts 142 and the conductive features 152. In some embodiments, the dielectric layer 151 includes or is made of a low-k dielectric material such as the examples of the low-k dielectric material suitable for forming the ILD layer 141 as described in the previous paragraph, but is not limited thereto. In some embodiments, each of the conductive features 152 includes or is made of a conductive material such as the examples of the conductive material suitable for forming the metal contacts 142 as described in the previous paragraph, but is not limited thereto. In some embodiments, the interconnect layer 15 may be formed by a single damascene process or a dual damascene process.

Referring to FIG. 1 and the examples illustrated in FIGS. 2 to 4, the method 1 begins at step S01, where a first metal-based dielectric layer 20 is formed on the interconnect layer 15 over the substrate 11. In some embodiments, the first metal-based dielectric layer 20 may serve as a glue layer which may enhance an adhesion between two adjacent layers. For the sake of brevity, the first metal-based dielectric layer 20 is referred to as a glue layer hereinafter.

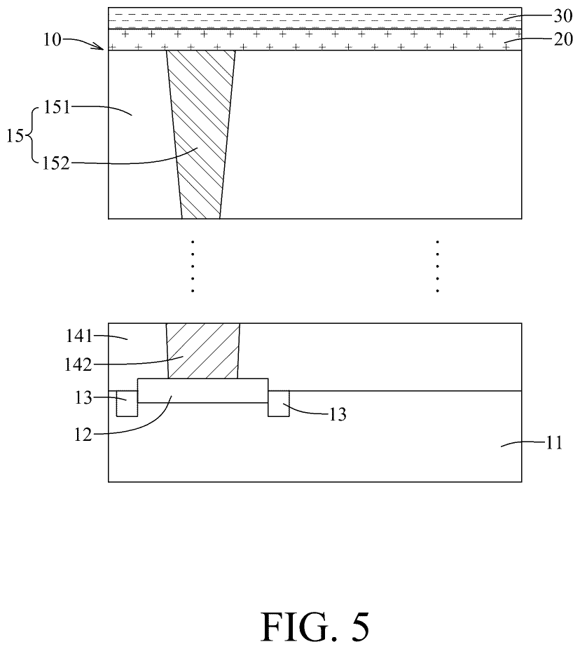

In some embodiments, the glue layer 20 is in contact with each of the dielectric layer 151 and the conductive features 152. The glue layer 20 includes or is made of a first metal-based dielectric material which includes nitrogen, such that both an adhesion between the glue layer 20 and the interconnect layer 15, and an adhesion between the glue layer 20 and a layer (e.g., a second metal-based dielectric layer 30 shown in FIG. 5) to be formed thereon may be enhanced. In some embodiments, the first metal-based dielectric material is free from carbon. In some embodiments, the first metal-based dielectric material includes metal nitride, metal oxynitride, or a combination thereof. In some embodiments, a metallic element in metal nitride or metal oxynitride includes aluminum, zirconium, hafnium, other suitable metals, or combinations thereof. In other words, metal nitride includes nitrides of aluminum, zirconium, hafnium, other suitable metals, or combinations thereof, and metal oxynitride includes oxynitrides of aluminum, zirconium, hafnium, other suitable metals, or combinations thereof. In some embodiments, the glue layer 20 has a thickness ranging from about 3 Å to about 5 Å, but other ranges of values are also within the contemplated scope of the present disclosure.

In some embodiments, the glue layer 20 is formed by atomic layer deposition (ALD, including thermal atomic layer deposition (thermal ALD), plasma-enhanced atomic layer deposition (PEALD)), or chemical vapor deposition (CVD) at a temperature ranging from about 300° C. to about 400° C. Deposition of the glue layer 20 may include the use of a metal-containing precursor gas and a reactant gas (including a nitrogen-containing reactant gas, or a combination of the nitrogen-containing reactant gas and an oxygen-containing reactant gas) for reacting with the metal-containing precursor gas. In some embodiments in which the metal-containing precursor gas additionally contains oxygen, the oxygen-containing reactant gas may be used in a reduced amount, or may be omitted. In the case that the glue layer 20 is formed by CVD, the metal-containing precursor gas and the reactant gas are simultaneously introduced into a CVD process chamber in which the base structure 10 is treated. In the case that the glue layer 20 is formed by ALD (e.g., thermal ALD or PEALD), the metal-containing precursor gas and the reactant gas are separately and repeatedly introduced into an ALD process chamber in which the base structure 10 is treated until the glue layer 20 with a desired thickness is obtained. It is noted that, in contrast to thermal ALD, the reactant gas used in PEALD, prior to being introduced into the ALD process chamber, is formed into a plasma state using, for example, a remote plasma generator, so that the temperature during formation of the glue layer 20 can be reduced. Other deposition techniques suitable for forming the glue layer 20 are also within the contemplated scope of the present disclosure.

In some embodiments in which the glue layer 20 includes or is made of metal nitride, a first metal-containing precursor and a first nitrogen-containing reactant are used to form the glue layer 20.

The first metal-containing precursor includes the metallic element for forming the glue layer 20, which includes or is made of metal nitride. In some embodiments, specific examples of the first metal-containing precursor include metal alkylate (such as trimethylaluminum, triethylaluminum, tripropylaluminum, tetramethyl hafnium, tetraethyl hafnium, tetrapropyl hafnium, tetramethyl zirconium, tetraethyl zirconium, and tetrapropyl zirconium), metal alkylamine (such as tetrakis(ethylmethylamino) zirconium (TEMAZr) or tetrakis(dimethylamido) hafnium (TDMAHf)), metal halide (such as hafnium chloride or zirconium chloride), or combinations thereof, but are not limited thereto. Other compounds suitable for providing the metallic element for forming the glue layer 20, which includes or is made of metal nitride, are also within the contemplated scope of the present disclosure.

The first nitrogen-containing reactant includes nitrogen for forming the glue layer 20, which includes or is made of metal nitride. In some embodiments, specific examples of the first nitrogen-containing reactant include ammonia, alkylamine (such as methylamine, ethylamine, or propylamine), alkanolamine (such as methanolamine, ethanolamine, or propanolamine), or combinations thereof, but are not limited thereto. Other compounds suitable for providing nitrogen for forming the glue layer 20, which includes or is made of metal nitride, are also within the contemplated scope of the present disclosure.

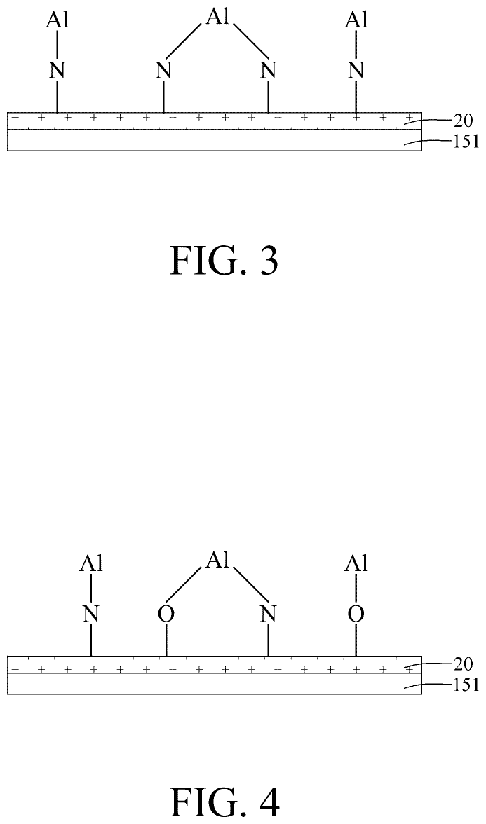

FIG. 3 is a schematic view illustrating a portion of the dielectric layer 151 and a portion of the glue layer 20 formed thereon in accordance with some embodiments. The glue layer 20, which is exemplarily shown in FIG. 3, is an aluminum nitride layer formed by ALD using aluminum alkylate (the first metal-containing precursor, for example, trimethylaluminum) and ammonia (the first nitrogen-containing reactant) that are alternately applied on the dielectric layer 151, and the deposition of the aluminum nitride layer is completed with the application of aluminum alkylate. As such, an upper surface of the aluminum nitride layer is formed with alkyl groups (for example, but not limited thereto, methyl groups). In some alternative embodiments, the deposition of the aluminum nitride layer may be completed with ammonia, and thus the upper surface of the aluminum nitride layer is formed with amino groups (—NH₂). In some embodiments, ammonia may be formed into a plasma state when the aluminum nitride layer is formed by PEALD.

In some embodiments in which the glue layer 20 includes or is made of metal oxynitride, a second metal-containing precursor, a second nitrogen-containing reactant and an oxygen-containing reactant are used to form the glue layer 20.

The second metal-containing precursor includes the metallic element for forming the glue layer 20, which includes or is made of metal oxynitride. In some embodiments, specific examples of the second metal-containing precursor include metal alkylate (such as trimethylaluminum, triethylaluminum, tripropylaluminum, tetramethyl hafnium, tetraethyl hafnium, tetrapropyl hafnium, tetramethyl zirconium, tetraethyl zirconium, and tetrapropyl zirconium), metal alkoxide (such as aluminum dimethyl iso-propoxide, Al(OC₂H₅)₃, Hf(OC(CH₃)₃)₄, or Zr(OC(CH₃)₃)₄), metal alkylamine (such as tetrakis(ethylmethylamino) zirconium (TEMAZr) or tetrakis(dimethylamido) hafnium (TDMAHf)), metal halide (such as hafnium chloride or zirconium chloride), or combinations thereof, but are not limited thereto. Other compounds suitable for providing the metallic element for forming the glue layer 20, which includes or is made of metal oxynitride, are also within the contemplated scope of the present disclosure.

The second nitrogen-containing reactant includes nitrogen for forming the glue layer 20, which includes or is made of metal oxynitride. Possible compounds suitable for serving as the second nitrogen-containing reactant are the same as or similar to those suitable for serving as the first nitrogen-containing reactant, and thus the details thereof are not repeated herein. Other compounds suitable for providing nitrogen for forming the glue layer 20, which includes or is made of metal oxynitride, are also within the contemplated scope of the present disclosure.

The oxygen-containing reactant includes oxygen for forming the glue layer 20, which includes or is made of metal oxynitride. In some embodiments, specific examples or of the oxygen-containing reactant include alcohol (such as methanol, ethanol, propanol), but are not limited thereto. Other compounds suitable for providing oxygen for forming the glue layer 20, which includes or is made of metal oxynitride, are also within the contemplated scope of the present disclosure. It is noted that when the second metal-containing precursor includes metal alkoxide, which also provides oxygen for forming the metal oxynitride layer, the use of the oxygen-containing reactant may be reduced or omitted according to practical applications.

FIG. 4 is a schematic view similar to that of FIG. 3, but the glue layer 20 exemplarily shown in FIG. 4 is an aluminum oxynitride layer which is formed by ALD using aluminum alkoxide (the second metal-containing precursor, for example, aluminum dimethyl iso-propoxide) and ammonia (the second nitrogen-containing reactant) that are alternately applied on the dielectric layer 151, and the deposition of the aluminum oxynitride layer is completed with the application of aluminum alkoxide. As such, an upper surface of the aluminum oxynitride layer is formed with alkyl groups (for example, but not limited thereto, methyl groups), alkoxy groups (for example, but not limited thereto, isopropoxy groups), or combinations thereof. In some alternative embodiments, the deposition of the aluminum oxynitride layer may be completed with ammonia, and thus the upper surface of the aluminum oxynitride layer is formed with amino groups. In some embodiments, ammonia may be formed into a plasma state when the aluminum oxynitride layer is formed by PEALD.

It is noted that functional groups formed on the upper surface of the aluminum nitride layer (or the aluminum oxynitride layer) depend on selection of precursors and reactants used in ALD and the application sequence of the precursors and reactants, and thus are not limited to those as described above.

Referring to FIG. 1 and the examples illustrated in FIGS. 5 to 9, the method 1 proceeds to step S02, where a second metal-based dielectric layer 30 is formed on the glue layer 20. FIG. 5 is a schematic view similar to that of FIG. 2, but illustrating the structure after step S02. In some embodiments, the second metal-based dielectric layer 30 may serve as an etch stop layer during a subsequent etching process. For the sake of brevity, the second metal-based dielectric layer 30 is referred to as an etch stop layer hereinafter.

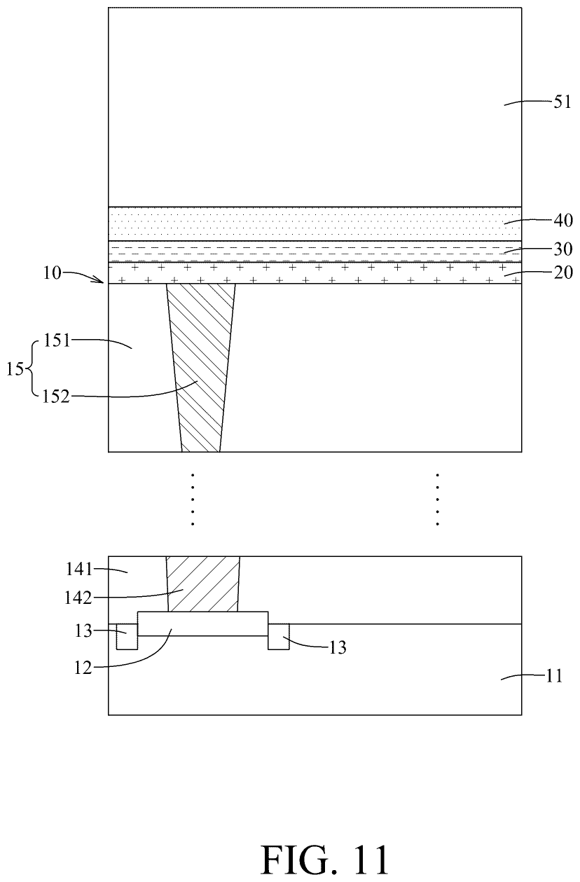

In some embodiments, the etch stop layer 30 is in contact with the glue layer 20. The etch stop layer 30 includes or is made of a second metal-based dielectric material which is different from the first metal-based dielectric material, and which is reacted with the first metal-based dielectric material to form a cross-linking structure. In some embodiments, the second metal-based dielectric material includes metal oxycarbide, metal oxycarbon nitride, or a combination thereof, which has a dielectric constant (k-value) lower than a dielectric constant of metal oxide. In some embodiments, the second metal-based dielectric material has a k-value that is lower than a k-value of the first metal-based dielectric material. In addition, the etch stop layer 30 has an etching selectivity to a dielectric layer (e.g., a dielectric layer 51 to be formed on the etch stop layer 30, as shown in FIG. 11) and is used to reduce etch rate during a subsequent process for patterning the dielectric layer. Furthermore, the etch stop layer 30 has an etching selectivity to the dielectric layer 51 that is not less than an etching selectivity of metal oxide to the dielectric layer 51. In some embodiments, a metallic element in metal oxycarbide or metal oxycarbon nitride includes aluminum, zirconium, hafnium, other suitable metals, or combinations thereof. In other words, metal oxycarbide includes oxycarbides of aluminum, zirconium, hafnium, other suitable metals, or combinations thereof, and metal oxycarbon nitride includes oxycarbon nitrides of aluminum, zirconium, hafnium, other suitable metals, or combinations thereof. The metallic element in the second metal-based dielectric material may be the same as or different from the metallic element in the first metal-based dielectric material. In some embodiments, the etch stop layer 30 has a thickness ranging from about 5 Å to about 10 Å, but other ranges of values are also within the contemplated scope of the present disclosure. In some embodiments, the thickness of the glue layer 20 is not greater than the thickness of the etch stop layer 30.

In some embodiments, the etch stop layer 30 is formed by ALD (e.g., thermal ALD or PEALD) which includes at least one deposition cycle. In some embodiments, formation of the etch stop layer 30 includes multiple deposition cycles. The number of the deposition cycles is positively correlated with the thickness of the etch stop layer 30 and may vary according to practical applications. In some embodiments, formation of the etch stop layer 30 is conducted at a temperature ranging from about 50° C. to about 350° C.

In some embodiments in which the etch stop layer 30 includes or is made of metal oxycarbide, in each deposition cycle, a third metal-containing precursor and a first carbon-containing and oxygen-containing reactant are separately applied on the glue layer 20 to form a monolayer of metal oxycarbide. In other words, the third metal-containing precursor and the first carbon-containing and oxygen-containing reactant are alternately applied on the glue layer 20 until the etch stop layer 30, which includes or is made of metal oxycarbide, with a desired thickness is obtained.

The third metal-containing precursor includes the metallic element for forming the etch stop layer 30, which includes or is made of metal oxycarbide. In some embodiments, the third metal-containing precursor includes an organometallic compound or a metal-organic compound including a central metal and functional groups coupled to the central metal. In some embodiments, the central metal includes aluminum, zirconium, hafnium, or other suitable metal. In some embodiments, the functional groups include an alkyl group, an alkoxy group, an alkylamino group, a halogen group, or combinations thereof. Possible compounds suitable for serving as the third metal-containing precursor are the same as or similar to those suitable for serving as the second metal-containing precursor, and thus the details thereof are not repeated herein. Other compounds suitable for providing the metallic element for forming the etch stop layer 30, which includes or is made of metal oxycarbide, are also within the contemplated scope of the present disclosure.

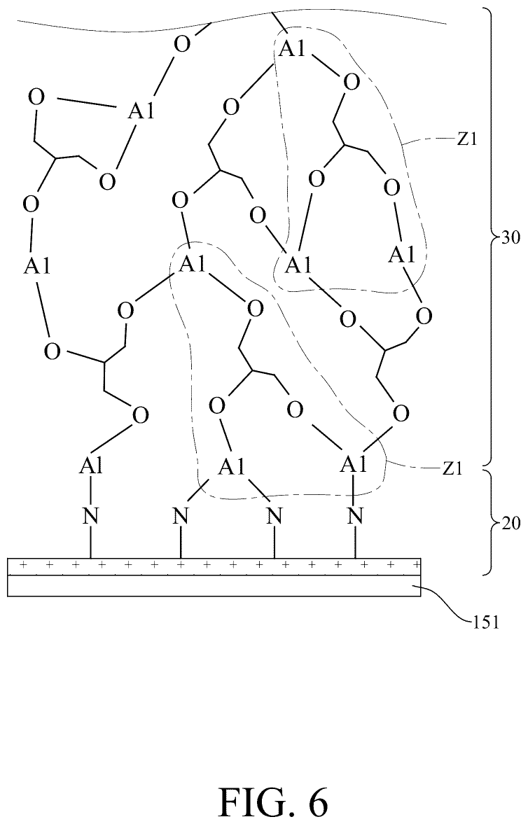

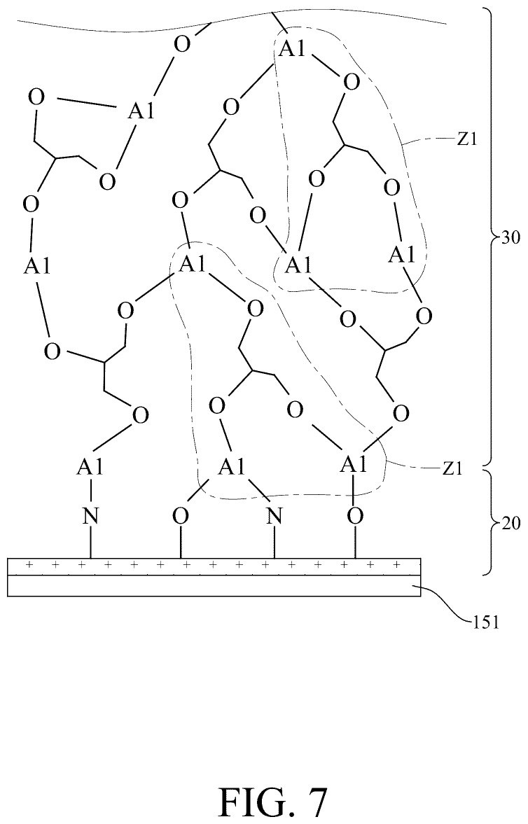

The first carbon-containing and oxygen-containing reactant includes carbon and oxygen which are used for forming the etch stop layer 30, which includes or is made of metal oxycarbide. The first carbon-containing and oxygen-containing reactant includes a multi-hydroxyl compound. The multi-hydroxyl compound includes at least three hydroxyl groups for reacting with the third metal-containing precursor so as to form a cross-linking structure (for example, but not limited to, areas indicated by Z1 shown in FIGS. 6 and 7). It is noted that in comparison with an etch stop layer that is formed using a carbon-containing and oxygen-containing reactant which includes one or two hydroxyl groups, occurrence of bond cleavage (bond broken) in the etch stop layer 30 (that is formed using a multi-hydroxyl compound including at least three hydroxyl groups) during subsequent thermal processes may be reduced. Thus, the etch stop layer 30 that is formed using the multi-hydroxyl compound has a relatively low porosity, thereby enhancing the reliability of the interconnect structure 100. In some embodiments, the etch stop layer 30 thus formed may have an electrical breakdown voltage (EBD) greater than about 4 MV/cm.

In some embodiments, the multi-hydroxyl compound is represented by Formula (I):

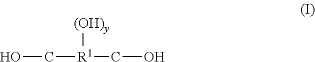

wherein
R¹ is methylene, ethylene, or propylene, and
y is an integer of not less than 1.

In the cross-linking structure, each oxygen (provided by the multi-hydroxyl compound) is coupled to a metal (provided by the third metal-containing precursor applied in the same deposition cycle or the next or previous deposition cycle).

To be specific, in some embodiments, in each deposition cycle, the third metal-containing precursor is absorbed onto the upper surface of the glue layer 20 and reacts with functional groups (e.g., amino groups) on the upper surface of the glue layer 20 until no functional groups are available for reaction, and then the first carbon-containing and oxygen-containing reactant is applied to react with the third metal-containing precursor so as to form a monolayer of metal oxycarbide. In some embodiments, prior to formation of the etch stop layer 30, which includes or is made of metal oxycarbide, a surface treatment process may be performed on the glue layer 20 such that the upper surface of the glue layer 20 is formed with hydroxyl groups, amine groups, or combinations thereof, such that the reaction between the third metal-containing precursor and the first metal-based dielectric material of the glue layer 20 may be facilitated, thereby increasing the adhesion between the glue layer 20 and the etch stop layer 30, which includes or is made of metal oxycarbide. In some embodiments, the surface treatment process includes a plasma treatment conducted using ammonia, alcohol (such as methanol, ethanol, or propanol), or a combination thereof.

In some alternative embodiments, in each deposition cycle, the first carbon-containing and oxygen-containing reactant is absorbed onto the upper surface of the glue layer 20 and reacts with functional groups (e.g., alkyl groups, alkoxy group, or other suitable ligands) on the upper surface of the glue layer 20 until no more functional groups to react, and then the third metal-containing precursor is applied to react with the first carbon-containing and oxygen-containing reactant so as to form a monolayer of metal oxycarbide.

For the sake of brevity and clarity, specific examples of the etch stop layer 30, which includes or is made of metal oxycarbide, are described below to illustrate the cross-linking structure of the present disclosure. FIGS. 6 and 7 are schematic views respectively similar to those of FIGS. 3 and 4, but each further illustrates the etch stop layer 30, which includes or is made of aluminum oxycarbide and which has a cross-linking structure, in accordance with some embodiments. As shown in FIG. 6, the etch stop layer 30, which includes or is made of aluminum oxycarbide, is formed on the glue layer 20, which includes or is made of aluminum nitride. As shown in FIG. 7, the etch stop layer 30, which includes or is made of aluminum oxycarbide, is formed on the glue layer 20, which includes or is made of aluminum oxynitride layer. In some embodiments, the etch stop layer 30, which includes or is made of aluminum oxycarbide, is formed by ALD using aluminum alkylate (the third metal-containing precursor, for example, trimethylaluminum) and glycerol (the first carbon-containing and oxygen-containing reactant) that are alternately applied on the glue layer 20 which includes or is made of aluminum nitride (see FIG. 6) or on the glue layer 20 which includes or is made of aluminum oxynitride (see FIG. 7).

Referring to FIGS. 6 and 7, in the cross-linking structure of the etch stop layer 30, which includes or is made of aluminum oxycarbide, any three adjacent aluminum atoms are coupled to a C3 carbon chain respectively through three oxygen atoms. It is noted that the C3 carbon chain and the three oxygen atoms (respectively from the three hydroxyl groups) in each area indicated by Z1, as shown in FIGS. 6 and 7, are provided by the same glycerol molecule. Therefore, with provision of the multi-hydroxyl compound (for example, but not limited to, glycerol), during formation of the etch stop layer 30, which includes or is made of aluminum oxycarbide, any three adjacent aluminum atoms of the etch stop layer 30 thus formed can be cross-linked with each other to form the cross-linking structure. Furthermore, aluminum atom(s) on the upper surface of the glue layer 20, which includes or is made of aluminum nitride or aluminum oxynitride, may also be cross-linked with aluminum atom(s) of the etch stop layer 30, which includes or is made of aluminum oxycarbide, through the C3 carbon chain and oxygen atoms provided by a single glycerol molecule.

In some embodiments in which the etch stop layer 30 includes or is made of metal oxycarbon nitride, in each deposition cycle, a fourth metal-containing precursor, a third nitrogen-containing reactant and a second carbon-containing and oxygen-containing reactant are sequentially applied on the glue layer 20 in such order to form a monolayer of metal oxycarbon nitride.

The fourth metal-containing precursor includes the metallic element for forming the etch stop layer 30, which includes or is made of metal oxycarbon nitride. In some embodiments, the fourth metal-containing precursor is the same as or similar to the third metal-containing precursor. Possible compounds suitable for serving as the fourth metal-containing precursor are the same as or similar to those suitable for serving as the third metal-containing precursor, and thus the details thereof are not repeated herein. Other compounds suitable for providing the metallic element for forming the etch stop layer 30, which includes or is made of metal oxycarbon nitride, are also within the contemplated scope of the present disclosure.

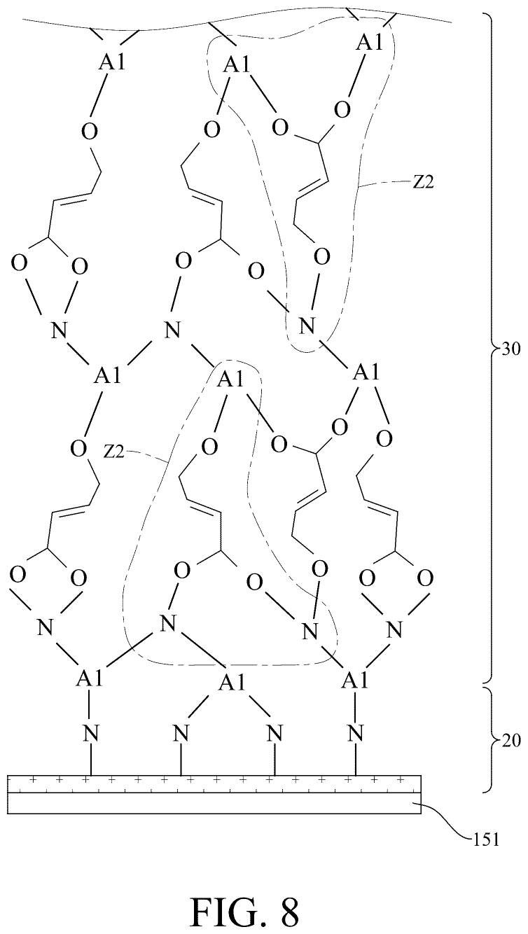

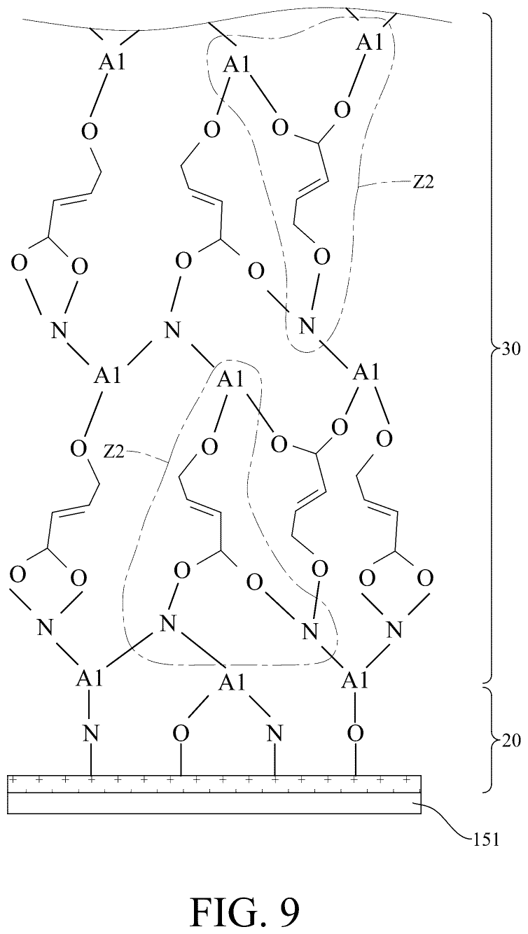

The second carbon-containing and oxygen-containing reactant includes carbon and oxygen which are used for forming the etch stop layer 30, which includes or is made of metal oxycarbon nitride. In some embodiments, specific examples of the second carbon-containing and oxygen-containing reactant include the multi-hydroxyl compound as described in the previous paragraph, a cyclic anhydride compound, or a combination thereof. The cyclic anhydride compound includes at least one anhydride functional group for reacting with the fourth metal-containing precursor and the third nitrogen-containing reactant so as to form a cross-linking structure (for example, but not limited to, areas indicated by Z2, as shown in FIGS. 8 and 9). It is noted that in comparison with an etch stop layer that is formed using a linear anhydride compound, occurrence of bond cleavage (bond broken) in the etch stop layer 30 (that is formed using a cyclic anhydride compound) during subsequent thermal processes may be reduced. Thus, the etch stop layer 30 that is formed using a cyclic anhydride compound has a relatively low porosity, thereby enhancing the reliability of the interconnect structure 100. In some embodiments, the etch stop layer 30 thus formed may have an electrical breakdown voltage (EBD) greater than about 4 MV/cm.

In some embodiments, the cyclic anhydride compound is represented by Formula (II)

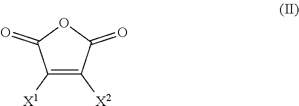

wherein each of X¹ and X² is independently hydrogen, methyl, ethyl, or propyl.

In the cross-linking structure, each oxygen (provided by the multi-hydroxyl compound or the cyclic anhydride compound) is coupled to a nitrogen (provided by the third nitrogen-containing reactant applied in the same deposition cycle) or a metal (provided by the fourth metal-containing precursor applied in the next deposition cycle).

To be specific, in some embodiments, in each deposition cycle, the fourth metal-containing precursor is absorbed onto the upper surface of the glue layer 20 and reacts with functional groups (e.g., amino groups) on the upper surface of the glue layer 20 until no more functional groups to react, and then the third nitrogen-containing reactant and the second carbon-containing and oxygen-containing reactant are sequentially applied in such order to react with the fourth metal-containing precursor, so as to form a monolayer of metal oxycarbon nitride. In some embodiments, prior to formation of the etch stop layer 30, which includes or is made of metal oxycarbon nitride, the surface treatment process as described above may be performed on the glue layer 20 such that the upper surface of the glue layer 20 is formed with hydroxyl groups, amine groups, or combinations thereof. As such, the reaction between the fourth metal-containing precursor and the first metal-based dielectric material of the glue layer 20 may be facilitated, thereby increasing the adhesion between the glue layer 20 and the etch stop layer 30, which includes or is made of metal oxycarbon nitride.

In some alternative embodiments, in each deposition cycle, the third nitrogen-containing reactant is absorbed onto the upper surface of the glue layer 20 and reacts with functional groups (e.g., alkyl groups, alkoxy group, or other suitable ligands) on the upper surface of the glue layer 20 until no more functional groups to react, and then the second carbon-containing and oxygen-containing reactant and the fourth metal-containing precursor are sequentially applied in such order so that the second carbon-containing and oxygen-containing reactant is reacted with the third nitrogen-containing reactant and then the fourth metal-containing precursor is reacted with the second carbon-containing and oxygen-containing reactant, thereby obtaining a monolayer of metal oxycarbon nitride.

For the sake of brevity and clarity, specific examples of the etch stop layer 30, which includes or is made of metal oxycarbon nitride, are described below to illustrate the cross-linking structure of the present disclosure. FIGS. 8 and 9 are schematic views respectively similar to those of FIGS. 3 and 4, but each further illustrates the etch stop layer 30, which includes or is made of aluminum oxycarbon nitride and which has a cross-linking structure, in accordance with some embodiments. As shown in FIG. 8, the etch stop layer 30, which includes or is made of aluminum oxycarbon nitride, is formed on the glue layer 20, which includes or is made of aluminum nitride. As shown in FIG. 9, the etch stop layer 30, which includes or is made of aluminum oxycarbon nitride, is formed on the glue layer 20, which includes or is made of aluminum oxynitride. In some embodiments, the etch stop layer 30, which includes or is made of aluminum oxycarbon nitride, is formed by ALD using aluminum alkylate (the fourth metal-containing precursor, for example, trimethylaluminum), ethanolamine (the third nitrogen-containing reactant) and maleic anhydride (the second carbon-containing and oxygen-containing reactant) that are sequentially and repeatedly applied on the glue layer 20 which includes or is made of aluminum nitride (see FIG. 8) or the glue layer 20 which includes or is made of aluminum oxynitride (see FIG. 9).

Referring to FIGS. 8 and 9, in the cross-linking structure of the etch stop layer 30, which includes or is made of aluminum oxycarbon nitride, any three adjacent aluminum atoms are coupled to a C4 carbon chain respectively through three oxygen atoms. It is noted that the C4 carbon chain and the three oxygen atoms (from one anhydride functional group) in each area of Z2, as shown in FIGS. 8 and 9, are provided by the same maleic anhydride molecule. Therefore, with provision of the cyclic anhydride compound (for example, but not limited to, maleic anhydride), during formation of the etch stop layer 30, which includes or is made of aluminum oxycarbon nitride, any three adjacent aluminum atoms of the etch stop layer 30 thus formed can be cross-linked with each other to form the cross-linking structure. Furthermore, aluminum atom(s) on the upper surface of the glue layer 20, which includes or is made of aluminum nitride or aluminum oxynitride, may also be cross-linked with aluminum atom(s) of the etch stop layer 30, which includes or is made of aluminum oxycarbon nitride, through the C4 carbon chain and oxygen atoms provided by a single maleic anhydride molecule.

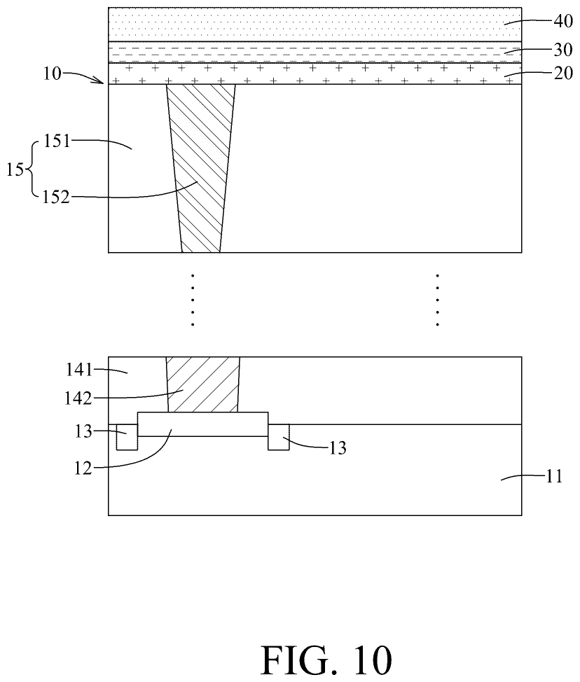

Referring to FIG. 1 and the example illustrated in FIG. 10, the method 1 proceeds to step S03, where a silicon-based dielectric layer 40 is formed on the etch stop layer 30. FIG. 10 is a schematic view similar to that of FIG. 5, but illustrating the structure after step S03. In some embodiments, the silicon-based dielectric layer 40 is used to block oxygen gas and/or moisture in the ambient atmosphere from penetrating into the interconnect layer 15 so as to prevent the conductive features 152 from being oxidized. For the sake of brevity, the silicon-based dielectric layer 40 is referred to as a cap layer.

In some embodiments, the cap layer 40 is in contact with the etch stop layer 30. The cap layer 40 includes or is made of a silicon-based dielectric material. In some embodiments, the silicon-based dielectric material includes silicon oxycarbide. In some embodiments, the cap layer 40 has a thickness that is greater than the thickness of the etch stop layer 30. In some embodiments, the thickness of the cap layer 40 ranges from about 30 Å to about 80 Å, but other ranges of values are also within the contemplated scope of the present disclosure.

In some embodiments, the cap layer 40 is formed by ALD (e.g., thermal ALD or PEALD), or CVD at a temperature ranging from about 300° C. to about 400° C. Formation of the cap layer 40 may include the use of a first precursor containing silicon and a second precursor containing carbon and oxygen. In some embodiments, the first precursor includes, for example, but not limited to, methylsilane, dimethylsilane, trimethylsilane, tetramethylsilane, methyldisilane, dimethyldisilane, trimethyldisilane, tetramethyldisilane, pentamethyldisilane, hexamethyldisilane, or combinations thereof. In some embodiments, the second precursor includes, for example, but not limited to, carbon dioxide, alcohol (such as methanol, ethanol, or propanol), or combinations thereof.

Referring to FIG. 1 and the example illustrated in FIG. 11, the method 1 proceeds to step S04, where a dielectric layer 51 is formed on the cap layer 40. FIG. 11 is a schematic view similar to that of FIG. 10, but illustrating the structure after step S04.

In some embodiments, the dielectric layer 51 may include a porous or non-porous low-k dielectric material, for example, but not limited to, silicon oxide, silicon oxycarbide, silicon oxycarbon nitride, or combinations thereof. Other low-k dielectric materials suitable for forming the dielectric layer 51 are within the contemplated scope of the present disclosure. In some embodiments, the low-k dielectric material of the dielectric layer 51 has a k value ranging from about 2.0 to about 4.0. In some embodiments, the dielectric layer 51 may be formed by CVD, ALD, PECVD, PEALD, spin coating, or other suitable deposition techniques. In some embodiments, formation of the dielectric layer 51 is conducted at a temperature ranging from about room temperature to about 420° C. When formation of the dielectric layer 51 is conducted at a temperature higher than 420° C., the components (for example, but not limited to, the conductive features 152) disposed beneath the dielectric layer 51 may be damaged (for example, but not limited to, wiggling or bending of the metal lines). In some embodiments, an annealing process, a plasma treatment process, or an ultraviolet (UV) treatment process may be conducted after the deposition process.

Referring to FIG. 1 and the example illustrated in FIG. 12, the method 1 proceeds to step S05, where conductive features 52 are formed in the dielectric layer 51 and each of the conductive features 52 penetrates each of the cap layer 40, the etch stop layer 30 and the glue layer 20 so as to be connected to a corresponding one of the conductive features 152. After step S05, the interconnect structure 100 including an interconnect layer 50 (including the dielectric layer 51 and the conductive features 52) is thus obtained. FIG. 12 is a schematic view similar to that of FIG. 11, but illustrating the structure after step S05.

In some embodiments, when each of the conductive features 152 is configured as a conductive via, each of the conductive features 52 is configured as a conductive line. In some embodiments, when each of the conductive features 152 is configured as a conductive line, each of the conductive features 52 is configured as a conductive via. In some embodiments, each of the conductive features 52 includes or is made of a conductive material such as the examples of the conductive material suitable for forming the metal contacts 142 as described in the previous paragraph, but is not limited thereto.

In some embodiments, formation of the conductive features 52 may include patterning the dielectric layer 51 to form at least one trench or at least one via opening (not shown) by a photolithography process and an etching process, depositing the conductive material of the conductive features 52 to fill the at least one trench or the at least one via opening by physical deposition, CVD, ALD, or other suitable deposition techniques, and performing a planarization process (e.g., chemical mechanical polishing) to remove an excess portion of the conductive material of the conductive features 52 until the dielectric layer 51 is exposed.

In some embodiments, the interconnect structure 100 may be further formed with another interconnect layer (not shown) which is formed over the interconnect layer 50. In some embodiments, the another interconnect layer may have a configuration similar to that of the interconnect layer 15. The another interconnect layer may be formed by a dual damascene process, a single damascene process, or other suitable back-end-of-line (BEOL) techniques.

In some embodiments, some steps in the method 1 may be modified, replaced, or eliminated without departure from the spirit and scope of the present disclosure. In some alternative embodiments, the interconnect structure 100 may further include additional features, and/or some features present in the interconnect structure 100 may be modified, replaced, or eliminated without departure from the spirit and scope of the present disclosure.

In the present disclosure, a multi-layered dielectric film scheme, which includes the glue layer 20, the etch stop layer 30 and the cap layer 40, is used for forming the interconnect structure 100. The glue layer 20 includes metal nitride, metal oxynitride, or a combination thereof, and thus the reliability performance (e.g., evaluated by a thermal torture test) of the interconnect structure 100 can be enhanced. The etch stop layer 30 includes metal oxycarbide, metal oxycarbon nitride, or a combination thereof, rather than metal oxide, and thus the interconnect structure 100 has a relatively low parasitic capacitance. In addition, by utilizing the multi-hydroxyl compound and/or the cyclic anhydride compound as a reactant which includes carbon and oxygen, the etch stop layer 30 thus formed has a cross-linking structure, which also enhances the reliability performance of the interconnect structure 100.

In accordance with some embodiments of the present disclosure, a method for manufacturing an interconnect structure includes: forming a first interconnect layer on a substrate, the first interconnect layer being formed with a first conductive feature; forming a first metal-based dielectric layer on the first interconnect layer, the first metal-based dielectric layer including a first metal-based dielectric material; forming a second metal-based dielectric layer on the first metal-based dielectric layer, the second metal-based dielectric layer including a second metal-based dielectric material which is different from the first metal-based dielectric material; and forming a second interconnect layer on the second metal-based dielectric layer, the second interconnect layer being formed with a second conductive feature that penetrates each of the second metal-based dielectric layer and the first metal-based dielectric layer, so that the second conductive feature is connected to the first conductive feature.

In accordance with some embodiments of the present disclosure, the first metal-based dielectric layer includes metal nitride, metal oxynitride, or a combination thereof.

In accordance with some embodiments of the present disclosure, the second metal-based dielectric layer includes metal oxycarbide. The second metal-based dielectric layer is formed by a deposition process which includes at least one deposition cycle, in which a metal-containing precursor and a carbon-containing and oxygen-containing reactant are sequentially applied on the first metal-based dielectric layer. The carbon-containing and oxygen-containing reactant includes a multi-hydroxyl compound, the multi-hydroxyl compound including at least three hydroxyl groups which react with the metal-containing precursor so as to form a cross-linking structure.

In accordance with some embodiments of the present disclosure, the multi-hydroxyl compound is represented by Formula (I):

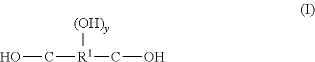

wherein
R¹ is methylene, ethylene, or propylene, and
y is an integer of not less than 1.

In accordance with some embodiments of the present disclosure, the metal-containing precursor includes an organometallic compound which includes an alkyl group, an alkoxy group, an alkylamino group, a halogen group, or combinations thereof.

In accordance with some embodiments of the present disclosure, the organometallic compound further includes aluminum, hafnium or zirconium.

In accordance with some embodiments of the present disclosure, the second metal-based dielectric stop layer includes metal oxycarbon nitride. The second metal-based dielectric layer is formed by a deposition process which includes at least one deposition cycle, in which a metal-containing precursor, a nitrogen-containing reactant, and a carbon-containing and oxygen-containing reactant are sequentially applied on the first metal-based dielectric layer. The carbon-containing and oxygen-containing reactant includes a cyclic anhydride compound, the cyclic anhydride compound including at least one anhydride functional group which reacts with the metal-containing precursor and the nitrogen-containing reactant so as to form a cross-linking structure.

In accordance with some embodiments of the present disclosure, the cyclic anhydride compound is represented by Formula (II):

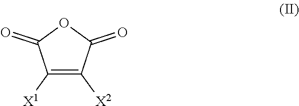

wherein each of X¹ and X² is independently hydrogen, methyl, ethyl, or propyl.

In accordance with some embodiments of the present disclosure, the metal-containing precursor includes an organometallic compound which includes an alkyl group, an alkoxy group, an alkylamino group, a halogen group, or combinations thereof.

In accordance with some embodiments of the present disclosure, the organometallic compound further includes aluminum, hafnium or zirconium.

In accordance with some embodiments of the present disclosure, the nitrogen-containing reactant includes alkylamine, alkanolamine, ammonia, or combinations thereof.

In accordance with some embodiments of the present disclosure, a method for manufacturing an interconnect structure includes: forming a first interconnect layer on a substrate, the first interconnect layer being formed with a first conductive feature; forming a first metal-based dielectric layer on the first interconnect layer, the first metal-based dielectric layer including a first metal-based dielectric material; forming a second metal-based dielectric layer on the first metal-based dielectric layer, the second metal-based dielectric layer including a second metal-based dielectric material that is different from the first metal-based dielectric material; forming a silicon-based dielectric layer on the second metal-based dielectric layer; and forming a second interconnect layer on the silicon-based dielectric layer, the second interconnect layer being formed with a second conductive feature that penetrates each of the silicon-based dielectric layer, the second metal-based dielectric layer and the first metal-based dielectric layer, so that the second conductive feature is connected to the first conductive feature.

In accordance with some embodiments of the present disclosure, the first metal-based dielectric material includes metal nitride, metal oxynitride, or a combination thereof, and the second metal-based dielectric material includes metal oxycarbide, metal oxycarbon nitride, or a combination thereof.

In accordance with some embodiments of the present disclosure, a dielectric constant of the first metal-based dielectric layer is greater than a dielectric constant of the second metal-based dielectric layer.

In accordance with some embodiments of the present disclosure, a thickness of the first metal-based dielectric layer is not greater than a thickness of the second metal-based dielectric layer.

In accordance with some embodiments of the present disclosure, the silicon-based dielectric layer includes silicon oxycarbide.

In accordance with some embodiments of the present disclosure, a thickness of the silicon-based dielectric layer is greater than a thickness of the second metal-based dielectric layer.

In accordance with some embodiments of the present disclosure, the first interconnect layer includes a dielectric portion and the first conductive feature which is formed in the dielectric portion, and the first metal-based dielectric layer is in contact with each of the dielectric portion and the first conductive feature.

In accordance with some embodiments of the present disclosure, an interconnect structure includes: a substrate; a first interconnect layer which is disposed on the substrate and which includes a first conductive feature; a first metal-based dielectric layer which is disposed on the first interconnect layer opposite to the substrate and which includes a first metal-based dielectric material; a second metal-based dielectric layer which is disposed on the first metal-based dielectric layer opposite to the first interconnect layer and which includes a second metal-based dielectric material that is different from the first metal-based dielectric material; a silicon-based dielectric layer which is disposed on the second metal-based dielectric layer opposite to the first metal-based dielectric layer; and a second interconnect layer which is disposed on the silicon-based dielectric layer opposite to the second metal-based dielectric layer and which includes a second conductive feature. The second conductive feature penetrates each of the silicon-based dielectric layer, the second metal-based dielectric layer and the first metal-based dielectric layer, so as to be connected to the first conductive feature.

In accordance with some embodiments of the present disclosure, the first metal-based dielectric layer includes metal nitride, metal oxynitride, or a combination thereof, the second metal-based dielectric layer includes metal oxycarbide, metal oxycarbon nitride, or a combination thereof, and the silicon-based dielectric layer includes silicon oxycarbide.

In accordance with some embodiments of the present disclosure, a method for manufacturing an interconnect structure includes: forming a first interconnect layer on a substrate, the first interconnect layer being formed with a first conductive feature; forming a first metal-based dielectric layer on the first interconnect layer, the first metal-based dielectric layer including a first metal-based dielectric material; forming a second metal-based dielectric layer on the first metal-based dielectric layer by atomic layer deposition, the second metal-based dielectric layer including a second metal-based dielectric material that is different from the first metal-based dielectric material; forming a silicon-based dielectric layer on the second metal-based dielectric layer; and forming a second interconnect layer on the silicon-based dielectric layer, the second interconnect layer being formed with a second conductive feature that penetrates each of the silicon-based dielectric layer, the second metal-based dielectric layer and the first metal-based dielectric layer, so that the second conductive feature is connected to the first conductive feature.

In accordance with some embodiments of the present disclosure, the first metal-based dielectric layer includes metal nitride, metal oxynitride, or a combination thereof, the second metal-based dielectric layer includes metal oxycarbide, metal oxycarbon nitride, or a combination thereof, and the silicon-based dielectric layer includes silicon oxycarbide.

The foregoing outlines features of several embodiments so that those skill ed in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing an interconnect structure, comprising:
forming a first interconnect layer on a substrate, the first interconnect layer being formed with a first conductive feature;
forming a first metal-based dielectric layer on the first interconnect layer, the first metal-based dielectric layer including a first metal-based dielectric material;
forming a second metal-based dielectric layer on the first metal-based dielectric layer, the second metal-based dielectric layer including a second metal-based dielectric material which is different from the first metal-based dielectric material; and
forming a second interconnect layer on the second metal-based dielectric layer, the second interconnect layer being formed with a second conductive feature that penetrates each of the second metal-based dielectric layer and the first metal-based dielectric layer, so that the second conductive feature is connected to the first conductive feature.

2. The method as claimed in claim 1, wherein the first metal-based dielectric layer includes metal nitride, metal oxynitride, or a combination thereof.

3. The method as claimed in claim 1, wherein
the second metal-based dielectric layer includes metal oxycarbide,
the second metal-based dielectric layer is formed by a deposition process which includes at least one deposition cycle, in which a metal-containing precursor and a carbon-containing and oxygen-containing reactant are sequentially applied on the first metal-based dielectric layer, and
the carbon-containing and oxygen-containing reactant includes a multi-hydroxyl compound, the multi-hydroxyl compound including at least three hydroxyl groups which react with the metal-containing precursor so as to form a cross-linking structure.

4. The method as claimed in claim 3, wherein
the multi-hydroxyl compound is represented by Formula (I): 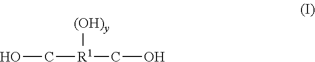
wherein
R¹ is methylene, ethylene, or propylene, and
y is an integer of not less than 1.

5. The method as claimed in claim 3, wherein the metal-containing precursor includes an organometallic compound which includes an alkyl group, an alkoxy group, an alkylamino group, a halogen group, or combinations thereof.

6. The method as claimed in claim 5, wherein the organometallic compound further includes aluminum, hafnium or zirconium.

7. The method as claimed in claim 1, wherein
the second metal-based dielectric layer includes metal oxycarbon nitride,
the second metal-based dielectric layer is formed by a deposition process which includes at least one deposition cycle, in which a metal-containing precursor, a nitrogen-containing reactant, and a carbon-containing and oxygen-containing reactant are sequentially applied on the first metal-based dielectric layer, and
the carbon-containing and oxygen-containing reactant includes a cyclic anhydride compound, the cyclic anhydride compound including at least one anhydride functional group which reacts with the metal-containing precursor and the nitrogen-containing reactant so as to form a cross-linking structure.

8. The method as claimed in claim 7, wherein the cyclic anhydride compound is represented by Formula (II): 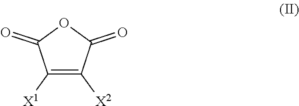
wherein each of X¹ and X² is independently hydrogen, methyl, ethyl, or propyl.

9. The method as claimed in claim 7, wherein the metal-containing precursor includes an organometallic compound which includes an alkyl group, an alkoxy group, an alkylamino group, a halogen group, or combinations thereof.

10. The method as claimed in claim 9, wherein the organometallic compound further includes aluminum, hafnium or zirconium.

11. The method as claimed in claim 7, wherein the nitrogen-containing reactant includes alkylamine, alkanolamine, ammonia, or combinations thereof.

12. A method for manufacturing an interconnect structure, comprising:
forming a first interconnect layer on a substrate, the first interconnect layer being formed with a first conductive feature;
forming a first metal-based dielectric layer on the first interconnect layer, the first metal-based dielectric layer including a first metal-based dielectric material;
forming a second metal-based dielectric layer on the first metal-based dielectric layer, the second metal-based dielectric layer including a second metal-based dielectric material that is different from the first metal-based dielectric material;
forming a silicon-based dielectric layer on the second metal-based dielectric layer; and
forming a second interconnect layer on the silicon-based dielectric layer, the second interconnect layer being formed with a second conductive feature that penetrates each of the silicon-based dielectric layer, the second metal-based dielectric layer and the first metal-based dielectric layer, so that the second conductive feature is connected to the first conductive feature.

13. The method as claimed in claim 12, wherein
the first metal-based dielectric material includes metal nitride, metal oxynitride, or a combination thereof, and
the second metal-based dielectric material includes metal oxycarbide, metal oxycarbon nitride, or a combination thereof.

14. The method as claimed in claim 12, wherein a dielectric constant of the first metal-based dielectric layer is greater than a dielectric constant of the second metal-based dielectric layer.

15. The method as claimed in claim 12, wherein a thickness of the first metal-based dielectric layer is not greater than a thickness of the second metal-based dielectric layer.

16. The method as claimed in claim 12, wherein the silicon-based dielectric layer includes silicon oxycarbide.

17. The method as claimed in claim 12, wherein a thickness of the silicon-based dielectric layer is greater than a thickness of the second metal-based dielectric layer.

18. The method as claimed in claim 12, wherein
the first interconnect layer includes a dielectric portion and the first conductive feature which is formed in the dielectric portion, and
the first metal-based dielectric layer is in contact with each of the dielectric portion and the first conductive feature.

19. An interconnect structure, comprising:
a substrate;
a first interconnect layer which is disposed on the substrate and which includes a first conductive feature;
a first metal-based dielectric layer which is disposed on the first interconnect layer opposite to the substrate and which includes a first metal-based dielectric material;
a second metal-based dielectric layer which is disposed on the first metal-based dielectric layer opposite to the first interconnect layer and which includes a second metal-based dielectric material that is different from the first metal-based dielectric material;
a silicon-based dielectric layer which is disposed on the second metal-based dielectric layer opposite to the first metal-based dielectric layer; and
a second interconnect layer which is disposed on the silicon-based dielectric layer opposite to the second metal-based dielectric layer and which includes a second conductive feature, the second conductive feature penetrating each of the silicon-based dielectric layer, the second metal-based dielectric layer and the first metal-based dielectric layer, so as to be connected to the first conductive feature.

20. The interconnect structure as claimed in claim 19, wherein
the first metal-based dielectric layer includes metal nitride, metal oxynitride, or a combination thereof,
the second metal-based dielectric layer includes metal oxycarbide, metal oxycarbon nitride, or a combination thereof, and
the silicon-based dielectric layer includes silicon oxycarbide.
